(19) United States
(12) Patent Application Publication
(10) Pub. No.: US 2006/0261387 A1
(43) Pub. Date: Nov. 23, 2006

(54) Semiconductor device and manufacturing method thereof

(75) Inventor: Kazutoshi Izumi, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/410,322

(22) Filed: Apr. 25, 2006

Related U.S. Application Data
(63) Continuation of application No. PCT/JP03/16986, filed on Dec. 26, 2003.

(51) Int. Cl. H01L 29/94

(52) U.S. Cl. 257/295

(57) ABSTRACT

A semiconductor device is disclosed. The semiconductor device includes a ferroelectric capacitor formed on a substrate and a wiring structure formed on the ferroelectric capacitor. The wiring structure includes a dielectric inter layer and a Cu wiring section formed in the dielectric inter layer. In addition, an etching stopper layer including a hydrogen diffusion preventing layer is formed so as to face the dielectric inter layer.

### CROSS-REFERENCE TO RELATED APPLICATION

This application is a U.S. continuation application filed under 35 USC 111(a) claiming benefit under 35 USC 120 and 365(c) of PCT application JP2003/016986, filed Dec. 26, 2003. The foregoing application is hereby incorporated herein by reference.

### BACKGROUND OF THE INVENTION

1. Field of the Invention

The present invention generally relates to a semiconductor device having a ferroelectric capacitor and a manufacturing method thereof.

2. Description of the Related Art

Recently, as a non-volatile memory which operates at highspeed and low power, a ferroelectric memory using a ferroelectric capacitor has been taken notice of and research and development of it has been greatly expanded.

For example, in the ferroelectric capacitor, a ferroelectric material having a perovskite crystal structure is used. That is, PZT (Pb(Zr, Ti)O₃), SBT (SrBi₂Ta₂O₉), and so on is used.

However, it is known that quality of the ferroelectric capacitor is degraded by hydrogen and water. Therefore, since the reduction of the quality of the ferroelectric capacitor must be prevented by preventing the diffusion of hydrogen and water, there is difficulty in manufacturing a high-quality semiconductor device having a ferroelectric capacitor (in some cases, hereinafter referred to as FeRAM).

For the semiconductor device having the ferroelectric capacitor, when the micro-fabrication of wirings progresses and the wiring rule becomes 0.18 μm or less, Cu is considered to be the wiring material corresponding to the micro-fabrication.

However, in a case where Cu is used as the wiring material, in some cases, the ferroelectric capacitor is damaged by the diffusion of hydrogen when the wiring structure is being formed. For example, an SiN film (silicon nitride film) formed by a plasma CVD (chemical vapor deposition) method is generally used as an etching stopper layer between insulation layers in which a trench wiring section or a via wiring section is formed. In this case, the ferroelectric capacitor is damaged by processes including hydrogen diffusion generated at the time of forming the SiN film.

In addition, in a manufacturing process of the semiconductor device, in order to increase the yield in manufacturing the semiconductor device by removing particles, a scrubber process (H₂O jet process) is generally executed. However, when the scrubber process is executed in the manufacturing process of the FeRAM, there is a risk that H₂O will be diffused and the ferroelectric capacity will be damaged, and further, it is difficult to execute the scrubber process after forming the ferroelectric capacitor. Consequently, in the manufacturing process of the FeRAM, it is difficult to increase the yield by removing the particles while preventing the deterioration of the ferroelectric capacitor caused by H₂O.

When the FeRAM is manufactured, in order to prevent the FeRAM from being damaged by the diffusion of hydrogen and the H₂O, in some cases, a hydrogen diffusion preventing layer is formed by, for example, Al₂O₃.

However, since components of the hydrogen diffusion preventing layer are different from those of an insulation layer formed near the hydrogen diffusion preventing layer, when contact wiring of the ferroelectric capacitor is formed by etching both the hydrogen diffusion preventing layer and the insulation layer, an etching gas and the etching conditions must be different between the hydrogen diffusion preventing layer and the insulation layer at the time of etching. In addition, etching must be executed on the hydrogen diffusion preventing layer and the insulation layer while the deterioration of the ferroelectric capacitor caused by the diffusion of hydrogen is prevented by forming the hydrogen diffusion preventing layer. Consequently, the efficiency at the time of forming the contact wiring of the ferroelectric capacitor becomes worse.

As conventional technologies regarding a semiconductor device or a manufacturing method of a semiconductor device, the following documents are disclosed.

[Patent document 1] Japanese Laid-Open Patent Application No. 8-321480

[Patent document 2] Japanese Laid-Open Patent Application No. 8-298252

[Patent document 3] Japanese Laid-Open Patent Application No. 8-1900

[Patent document 4] Japanese Laid-Open Patent Application No. 2002-358537

[Patent document 5] Japanese Laid-Open Patent Application No. 2002-176149

[Patent document 6] Japanese Laid-Open Patent Application No. 2002-43541

[Patent document 7] Japanese Laid-Open Patent Application No. 2002-100742

### SUMMARY OF THE INVENTION

Accordingly, the present invention may provide a novel and effective semiconductor device and a manufacturing method thereof by solving the above problems.

An embodiment of the present invention may provide a semiconductor device having a high-quality ferroelectric capacitor in which the ferroelectric capacitor is prevented from being damaged by preventing the diffusion of hydrogen or H₂O.

An embodiment of the present invention may provide a semiconductor device having a high-quality ferroelectric capacitor and a manufacturing method thereof, in which the ferroelectric capacitor is prevented from being damaged by the diffusion of hydrogen when a wiring structure of the semiconductor device is formed of Cu.

Another embodiment of the present invention may provide a manufacturing method of a semiconductor device having a high-quality ferroelectric capacitor, in which the yield in manufacturing the semiconductor device is increased by removing particles while preventing the deterioration of the ferroelectric capacitor caused by H₂O.

Another embodiment of the present invention may provide a manufacturing method of a semiconductor device having a high-quality ferroelectric capacitor, in which the efficiency at the time of forming contact wiring by etching a hydrogen diffusion preventing layer and an insulation layer is increased while the deterioration of the ferroelectric capacitor caused by the diffusion of hydrogen is prevented by forming the hydrogen diffusion preventing layer.

According to an aspect of the present invention, there is provided a semiconductor device which includes a ferroelectric capacitor formed on a substrate and a wiring structure formed on the ferroelectric capacitor. The wiring structure includes a dielectric inter layer and a Cu wiring section formed in the dielectric inter layer, and an etching stopper layer including a hydrogen diffusion preventing layer is formed so as to face the dielectric inter layer.

According to an embodiment of the present invention, since the etching stopper layer including the hydrogen diffusion preventing layer is formed so as to face the dielectric inter layer, deterioration of the ferroelectric capacitor can be prevented by preventing the diffusion of hydrogen.

In addition, according to another aspect of the present invention, there is provided a manufacturing method of a semiconductor device which includes a step of forming a ferroelectric capacitor on a substrate and a step of forming a wiring structure on the ferroelectric capacitor. The step of forming the wiring structure includes a step of forming a first wiring structure which includes a wiring section and a first dielectric inter layer on the ferroelectric capacitor, a step of forming an etching stopper layer which includes a hydrogen diffusion preventing layer on the first wiring structure, and a step of forming a second wiring structure which includes a Cu wiring section and a second dielectric inter layer on the etching stopper layer.

According to the manufacturing method of the semiconductor device of the present invention, when the wiring structure is formed on the ferroelectric capacitor, since the etching stopper layer for the dielectric inter layer includes the hydrogen diffusion preventing layer, deterioration of the ferroelectric capacitor can be prevented by preventing the diffusion of hydrogen.

In addition, according to another aspect of the present invention, there is provided a manufacturing method of a semiconductor device which includes a step of forming a ferroelectric capacitor on a substrate and a step of forming a wiring structure on the ferroelectric capacitor. The manufacturing method includes a low temperature aerosol cleaning step by an inactive gas.

According to the manufacturing method of the semiconductor device, since the low temperature aerosol cleaning method is used, the yield in manufacturing the semiconductor device can be increased by removing particles while preventing the deterioration of the ferroelectric capacitor.

In addition, according to another aspect of the present invention, there is provided a manufacturing method of a semiconductor device. The manufacturing method includes a step of forming a ferroelectric capacitor on a substrate, a step of forming an insulation layer on the ferroelectric capacitor so that a protrusion of the insulation layer is formed on the ferroelectric capacitor by a high density plasma CVD method, a step of forming a hydrogen diffusion preventing layer on the insulation layer, a step of forming an exposure section so that a part of the insulation layer is exposed by selectively removing a part of the hydrogen diffusion preventing layer on the protrusion by a CMP method, and a step of forming contact wiring in a contact hole formed from the exposure section to an electrode of the ferroelectric capacitor.

According to the manufacturing method of the semiconductor device, since the deterioration of the ferroelectric capacitor is prevented by preventing the diffusion of hydrogen and H₂O by forming the hydrogen diffusion preventing layer where a part of the hydrogen diffusion preventing layer is selectively removed, etching efficiency at the time of forming contact wiring can be increased.

### BRIEF DESCRIPTION OF THE DRAWINGS

Other objects and further features of the present invention will be apparent from the following detailed description when read in conjunction with the accompanying drawings.

FIG. 1 is a schematic cross-sectional view of a semiconductor device having a ferroelectric capacitor according to a first embodiment of the present invention;

FIGS. 2A through 2C are diagrams showing processes to form the ferroelectric capacitor and a first wiring structure of the semiconductor device shown in FIG. 1;

FIGS. 3A through 3C are diagrams showing processes to form a second wiring structure of the semiconductor device shown in FIG. 1;

FIGS. 4A through 4D are diagrams showing processes to form a third wiring structure and a fourth wiring structure of the semiconductor device shown in FIG. 1;

FIG. 5 is a schematic diagram showing a low temperature aerosol cleaning method which is used in a manufacturing method of the semiconductor device shown in FIG. 1; and

FIGS. 6A through 6F are diagrams showing processes to form a wiring structure of a semiconductor device according to a second embodiment of the present invention.

### DESCRIPTION OF THE PREFERRED EMBODIMENTS

Referring to the drawings, embodiments of the present invention are explained.

### First Embodiment

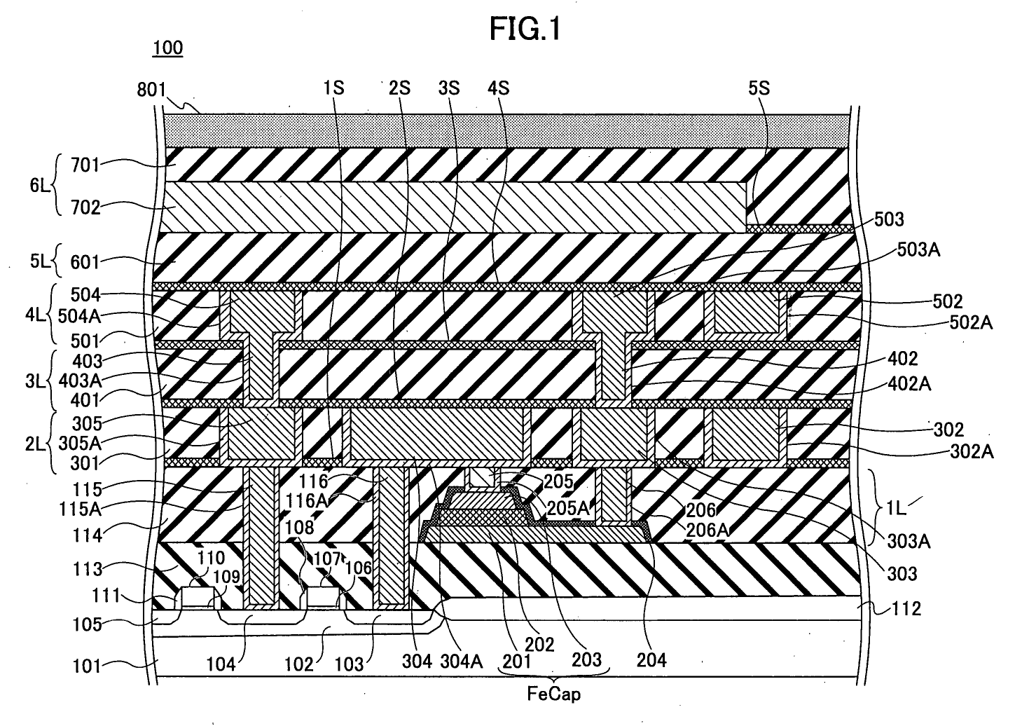

FIG. 1 is a schematic cross-sectional view of a semiconductor device 100 which has a ferroelectric capacitor according to a first embodiment of the present invention.

As shown in FIG. 1, the semiconductor device 100 has a ferroelectric capacitor that is formed on a layer in which layer a transistor and so on are formed on a silicon substrate 101, and a multi-layer wiring structure is formed on the ferroelectric capacitor.

The transistor is formed in an element region isolated by an element isolation insulating layer 112 on the silicon substrate 101. In the element region, an impurity diffusion layer 102 is formed to surround impurity diffusion layers 103, 104, and 105.

A gate insulation layer 106 is formed on the silicon substrate 101 sandwiched between the impurity diffusion layers 103 and 104. A gate electrode 107 is formed on the gate insulation layer 106, and a side wall insulation layer 108 is formed on the side wall of the gate electrode 107. With this, a MOS transistor is formed.

Similarly, a gate insulation layer 109 is formed on the silicon substrate 101 sandwiched between the impurity diffusion layers 104 and 105. A gate electrode 110 is formed on the gate insulation layer 109, and a side wall insulation layer 111 is formed on the side wall of the gate electrode 110. With this, another MOS transistor is formed.

An insulation layer 113 is formed to cover the MOS transistors, and a ferroelectric capacitor FeCap is formed on the insulation layer 113.

The ferroelectric capacitor FeCap includes a lower electrode 201 formed on the insulation layer 113, a ferroelectric layer 202 formed on the lower electrode 201, and an upper electrode 203 formed on the ferroelectric layer 202.

In addition, a hydrogen diffusion preventing layer 204 made of, for example, Al₂O₃ is formed to cover the ferroelectric capacitor FeCap. As described above, it is known that the ferroelectric capacitor is damaged by hydrogen and H₂O; therefore, the hydrogen diffusion preventing layer 204 prevents the ferroelectric capacitor FeCap from being exposed to hydrogen and H₂O.

However, for example, to form a wiring structure after the ferroelectric capacitor is formed, when a process is performed that causes the diffusion of hydrogen to the ferroelectric capacitor, for example, a process that forms an SiN film as an etching stopper layer for a dielectric inter layer, the influence of the diffusion of the hydrogen is large and the hydrogen diffusion preventing effect is not enough. Consequently, the ferroelectric capacitor is damaged. In order to solve this problem, in the present embodiment, the etching stopper layer includes the hydrogen diffusion preventing layer. This is described below in detail.

A dielectric inter layer 114 is formed by covering the hydrogen diffusion preventing layer 204 and the insulation layer 113, plural contact holes are formed in the dielectric inter layer 114, and contact wiring is formed in the contact holes. With this, a first wiring structure 1L is formed.

That is, contact wiring 206 is formed around which a barrier film 206A is formed so that the contact wiring 206 is electrically connected to the lower electrode 201. In addition, contact wiring 205 is formed around which a barrier film 205A is formed so that the contact wiring 205 is electrically connected to the upper electrode 203.

In addition, contact wiring 116 is formed around which a barrier film 116A is formed passing through the dielectric inter layer 114 and the insulation layer 113 so that the contact wiring 116 is electrically connected to the impurity diffusion layer 103.

Similarly, contact wiring 115 is formed around which a barrier film 115A is formed passing through the dielectric inter layer 114 and the insulation layer 113 so that the contact wiring 115 is electrically connected to the impurity diffusion layer 104.

An etching stopper layer 1S is formed on the dielectric inter layer 114 of the first wiring structure 1L. The etching stopper layer 1S functions as an etching stopper when a dielectric inter layer 301 formed on the etching stopper layer 1S is being patterned.

The dielectric inter layer 301 is formed on the etching stopper layer 1S, and plural trench wiring sections (described below) are formed in the dielectric inter layer 301. With this, a second wiring structure 2L is formed.

For example, a trench wiring section 302 is formed in a trench formed in the dielectric inter layer 301 so that the trench wiring section 302 is surrounded by a barrier film 302A.

Similarly, a trench wiring section 303 is formed in a trench formed in the dielectric inter layer 301 so that the trench wiring section 303 is surrounded by a barrier film 303A and is electrically connected to the contact wiring 206.

In addition, a trench wiring section 304 is formed in a trench formed in the dielectric inter layer 301 so that the trench wiring section 304 is surrounded by a barrier film 304A and is electrically connected to the contact wirings 205 and 116.

Further, a trench wiring section 305 is formed in a trench formed in the dielectric inter layer 301 so that the trench wiring section 305 is surrounded by a barrier film 305A and is electrically connected to the contact wiring 115.

An etching stopper layer 2S is formed on the second wiring structure 2L in contact with the dielectric inter layer 301. A dielectric inter layer 401 is formed on the etching stopper layer 2S and plural via plug wiring sections (described below) are formed in the dielectric inter layer 401. With this, a third wiring structure 3L is formed.

For example, a via plug wiring section 402 is formed in a via hole formed in the dielectric inter layer 401 so that the via plug wiring section 402 is surrounded by a barrier film 402A and is electrically connected to the trench wiring section 303.

Similarly, a via plug wiring section 403 is formed in a via hole formed in the dielectric inter layer 401 so that the via plug wiring section 403 is surrounded by a barrier film 403A and is electrically connected to the trench wiring section 305.

Like the above, an etching stopper layer 3S is formed on the third wiring structure 3L and a fourth wiring structure 4L is formed on the etching stopper layer 3S. The fourth wiring structure 4L has a dielectric inter layer 501 in which plural trench wiring sections are formed.

Trench wiring sections 502, 503, and 504 are formed in the dielectric inter layer 501 of the fourth wiring structure 4L so that the trench wiring sections 502, 503, and 504 are surrounded by corresponding barrier films 502A, 503A,and 504A.

Further, an etching stopper layer 4S is formed on the fourth wiring structure 4L and a fifth wiring structure 5L is formed on the etching stopper layer 4S. The fifth wiring structure 5L has a dielectric inter layer 601 in which plural via plug wiring sections (not shown) are formed.

An etching stopper layer 5S is formed on the fifth wiring structure 5L, and a dielectric inter layer 701, in which a global wiring section 702 is formed, is formed on the etching stopper layer 5S.

In addition, a protection film 801 is formed on the dielectric inter layer 701.

The trench wiring sections 302, 303, 304, 305, 502, 503, and 504, and the via plug wiring sections 402 and 403 are made of Cu. The barrier films 302A, 303A, 304A, 305A, 402A, 403A, 502A, 503A, and 504A are made of, for example, Ta or TaN.

The global wiring section 702 is made of Cu; however, it can be made of Al.

Conventionally, the etching stopper layers 1S to 5S are generally formed by a SiN layer in the wiring structures including Cu wiring sections. The SiN layer is an etching stopper and prevents the diffusion of Cu.

However, in a semiconductor device having a ferroelectric capacitor, damage including due to the diffusion of hydrogen is inflicted on the ferroelectric capacitor when the SiN layer is formed by a plasma CVD. (chemical vapor deposition) method. Consequently, the ferroelectric capacitor deteriorates.

In order to solve this problem, in the present embodiment, a film including a hydrogen diffusion preventing layer is used as the etching stopper layer. For example, as the etching stopper layer, any one of an Al oxide, an Al nitride, a Ta oxide, a Ta nitride, a Ti oxide, and a Zr oxide can be used. In this case, the diffusion of hydrogen and H₂O can be prevented by forming the etching stopper layer using the above materials.

Further, as described above, the Al oxide (for example, Al₂O₃), the Al nitride, the Ta oxide, the Ta nitride, the Ti oxide, and the Zr oxide can be used as the etching stopper when etching is applied to a dielectric inter layer, and can also function as a Cu diffusion preventing layer. That is, the etching stopper layer can function as the prevention of the diffusion of hydrogen, the stopper at the etching process, and the prevention of the diffusion of Cu.

In addition, as the etching stopper layer, for example, an SiO layer, an SiON layer, and so on can be used. In this case, when a suitable amount of nitrogen is added to the SiO layer, the effect of preventing the diffusion of Cu can be increased. However, when the added amount is large, the diffusion of hydrogen is facilitated. Therefore, a balance between preventing the Cu diffusion and preventing the hydrogen diffusion can be maintained depending on the amount of added nitrogen.

The SiN layer has excellence in preventing the Cu diffusion; however, it has a negative influence on the hydrogen diffusion. Therefore, when the SiN layer is used as the etching stopper layer, by stacking the SiN layer with a hydrogen diffusion preventing layer, the stacked layer can prevent hydrogen diffusion, stop the etching, and prevent Cu diffusion. Especially, the prevention of Cu diffusion becomes excellent. As the hydrogen diffusion preventing layer, a layer made of any one of, for example, an Al oxide, an Al nitride, a Ta oxide, a Ta nitride, a Ti oxide, and a Zr oxide is suitable. These are chemical compounds of metal that are excellent in preventing the hydrogen diffusion.

As described above, when the etching stopper layer is formed by the above stacked structure, excellent prevention of hydrogen diffusion, etching stopping, and prevention of Cu diffusion are realized. For example, when a layer made of any one of an Al oxide, an Al nitride, a Ta oxide, a Ta nitride, a Ti oxide, and a Zr oxide, is stacked on an SiO layer or an SiON layer, excellent results can be obtained.

In addition, the etching stopper layer is not limited to the above materials. A material, which is excellent in preventing hydrogen diffusion, stopping etching, and preventing Cu diffusion, can be used by stacking on one of the above materials or mixing with the above materials.

[Manufacturing Method 1]

Next, referring to the drawings, a manufacturing method of the semiconductor device 100 is explained. First, a manufacturing method of a ferroelectric capacitor is explained, and then, a manufacturing method of wiring structures is explained.

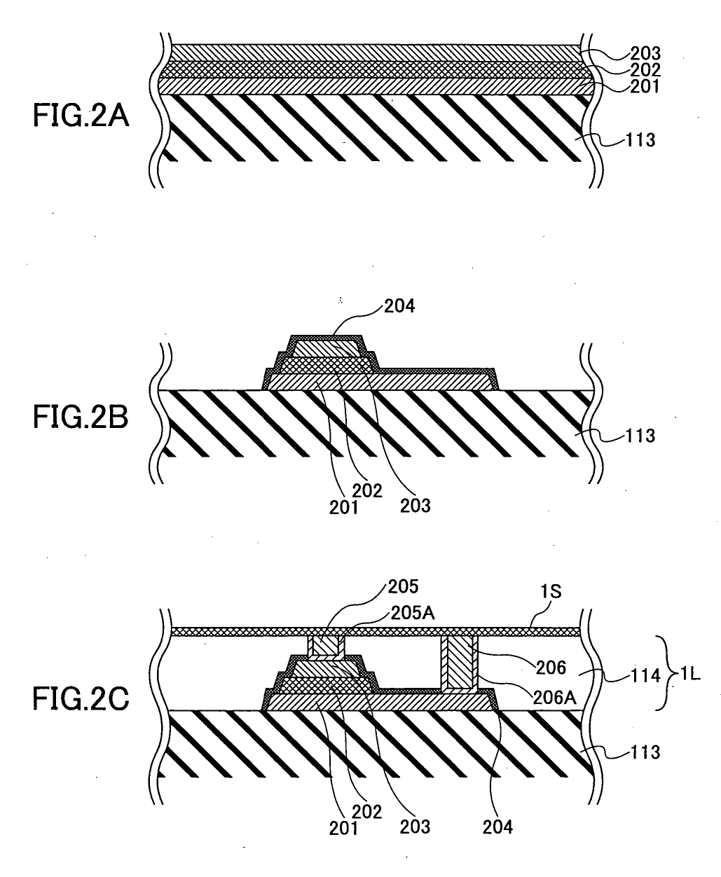

FIGS. 2A through 2C are diagrams showing processes to form the ferroelectric capacitor FeCap and the first wiring structure 1L of the semiconductor device 100. In FIGS. 2A through 2C, a part of the cross section of the semiconductor device 100 is shown, and the other parts thereof are omitted. Explanation of repeated processes is omitted.

In a process shown in FIG. 2A, the lower electrode 201, the ferroelectric layer 202, and the upper electrode 203 are formed on the insulation layer 113.

First, on the insulation layer 113, the lower electrode 201 made of, for example, Ir, is formed by sputtering so that the thickness thereof becomes, for example, 200 nm. Next, on the lower electrode 201, the ferroelectric layer 202 made of, for example, PZT (Pb(Zr, Ti)O₃), is formed so that the thickness thereof becomes, for example, 150 nm.

When the ferroelectric layer 202 of PZT is formed, either of a sputtering method and an MOCVD (metal organic chemical vapor deposition) method can be used. In one case, the spluttering method is used at the early part of the forming and then the forming is continued with the MOCVD method. With this, a PZT film is formed.

Next, on the ferroelectric layer 202, the upper electrode 203 made of, for example, Ir, is formed by sputtering so that the thickness thereof becomes, for example, 200 nm.

In this case, for the lower electrode 201 and the upper electrode 203, a metal such as Pr can be used in place of Ir; in addition, a conductive oxide such as IrOx, PtOx, and PtIrOx can be used. Further, as a lower electrode diffusion barrier, a layer made of Ti or a conductive nitride such as TiN can be formed.

The material of the ferroelectric layer 202 is not limited to PZT; other ferroelectric materials such as SBT (SrBi₂Ta₂O₉) can be used.

In addition, when annealing is applied after forming the lower electrode 201, the ferroelectric layer 202, or the upper electrode 203, film (layer) quality is improved. For example, if annealing is applied in a temperature range of 400° C. to 700° C. after forming the ferroelectric layer 202, the film quality of the ferroelectric layer 202 becomes excellent.

Next, in a process shown in FIG. 2B, pattering of the ferroelectric capacitor is executed by etching the upper electrode 203, the ferroelectric layer 202, and the lower electrode 201. Next, the hydrogen diffusion preventing layer 204 made of, for example, Al₂O₃ is formed so that the thickness thereof becomes 10 nm to 100 nm.

When the hydrogen diffusion preventing layer 204 is formed, any one of the sputtering method, the MOCVD method, and a method using hydrolysis can be used. In addition, for the hydrogen diffusion preventing layer 204, a material that prevents hydrogen diffusion can be used in place of Al₂O₃. For example, an Al nitrogen oxide, a Ta oxide, or a Ti oxide can be used.

Next, in a process shown in FIG. 2C, the dielectric inter layer 114 is formed on the hydrogen diffusion preventing layer 204 to cover all the surfaces of the ferroelectric capacitor by, for example, a plasma TEOS (tetra ethyl ortho silicate) method or a spin coat method.

In addition, when an annealing process or a plasma process is applied after forming the dielectric inter layer 114, the film quality is increased due to elimination of water and so on. Further, deterioration of the ferroelectric capacitor can be prevented by eliminating water and hydrogen.

Next, patterning is applied to the dielectric inter layer 114 by a photolithography method and contact holes connecting to the upper electrode 203 and the lower electrode 201 are formed by etching. The contact wirings 205 and 206 which are electrically connected to the corresponding upper and lower electrodes 203 and 201 are formed in the contact holes. With this, the first wiring structure 1L is formed. The contact wirings 205 and 206 are formed to be surrounded by the corresponding barrier films 205A and 206A.

The contact wirings 205 and 206 are made of, for example, W (tungsten); in this case, the barrier films 205A and 206A are made of TiN or Ti/TiN.

In addition, the contact wirings 205 and 206 can be made of Al or Cu. In this case, when Al or Cu is compared with W which is formed by a CVD method which uses, for example, a reducing gas including hydrogen, the deterioration of the ferroelectric capacitor can be restrained by eliminating the influence of hydrogen.

When the contact wirings 205 and 206 are made of Al, after forming an Al layer, patterning is applied to the Al layer by RIE (reactive ion etching). Then Al wirings are formed, and after this, a dielectric inter layer is formed at the position where the Al wirings are not formed.

In addition, when the contact wirings 205 and 206 are made of Cu, the electric resistance is lowered. Further, since the wiring structure can be formed by a damascene method, the micro-fabrication of the wirings can be easy.

Further, when the contact wirings 205 and 206 are made of Al, it is preferable that the barrier films 205A and 206A be made of TiN or Ti/TiN. When the contact wirings 205 and 206 are made of Cu, it is preferable that the barrier films 205A and 206A be made of Ta or TaN.

In addition, after forming the contact holes and before forming the contact wirings 205 and 206, when an annealing process of 400° C. to 600° C. is applied for restoring the ferroelectric capacitor from being deteriorated, hydrogen and water diffused before can be removed and the ferroelectric capacitor can recover from the deterioration.

Next, the etching stopper layer 1S made of, for example, Al₂O₃ is formed to cover the dielectric inter layer 114 and the contact wirings 205 and 206. In a case where the etching stopper layer 1S is formed, any one of the sputtering method, the MOCVD method, and a hydrolysis method using the following reaction can be used.
2AlCl₃+3H₂O→Al₂O₃+↑6HCl

In addition, when the etching stopper layer 1S is formed, there is a method in which the sputtering method is used first and then the CVD method is used on a film formed by the sputtering method. In this case, when an annealing process of 300° C. to 600° C. is applied after the sputtering process, the film quality can be excellent.

As described above, various materials can be used for the etching stopper layer 1S. The etching stopper layers 2S through 5S can be formed by the same materials and methods as those for the etching stopper layer 1S.

As described above, the ferroelectric capacitor and the first wiring structure 1L on the ferroelectric capacitor are formed. Next, the wiring structures above the first wiring structure 1L are formed by the following processes.

[Manufacturing Method 2]

Next, referring to the drawings, a manufacturing method of the wiring structures above the first wiring structure 1L is explained.

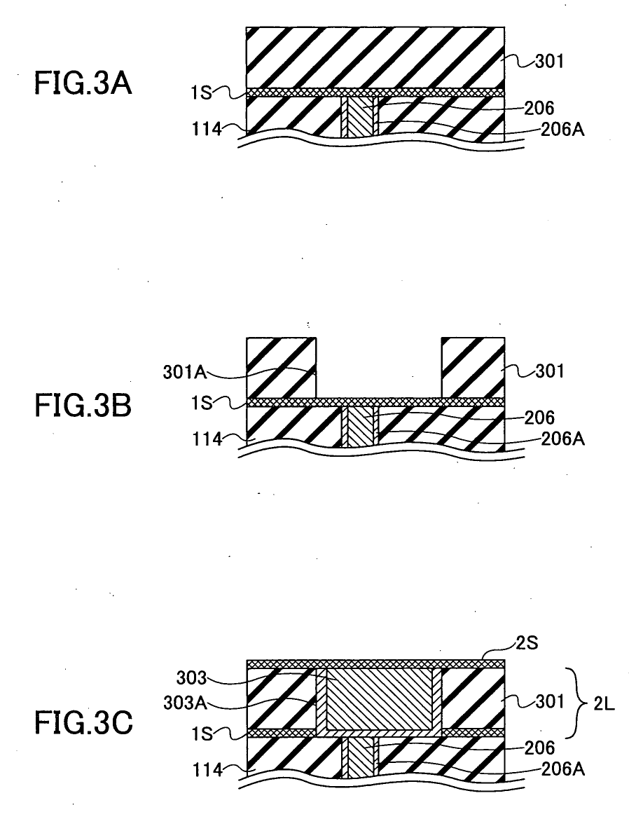

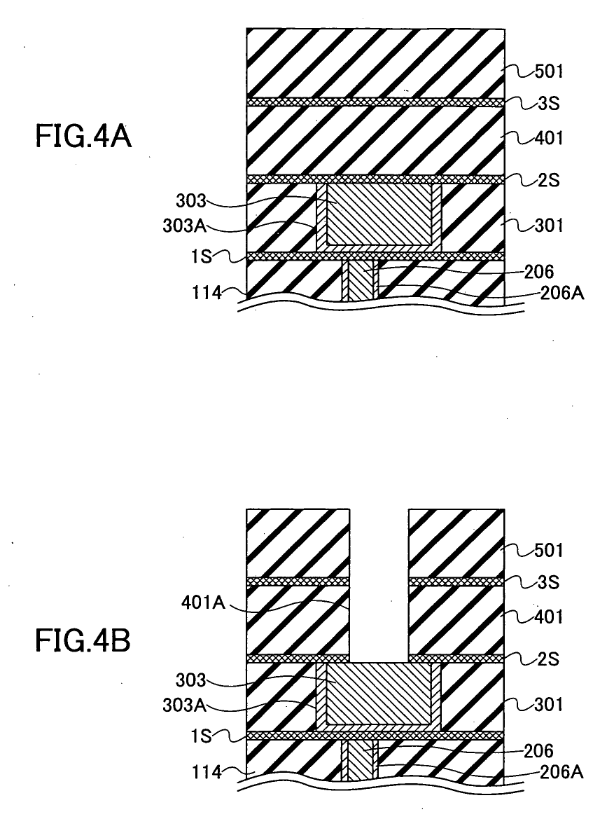

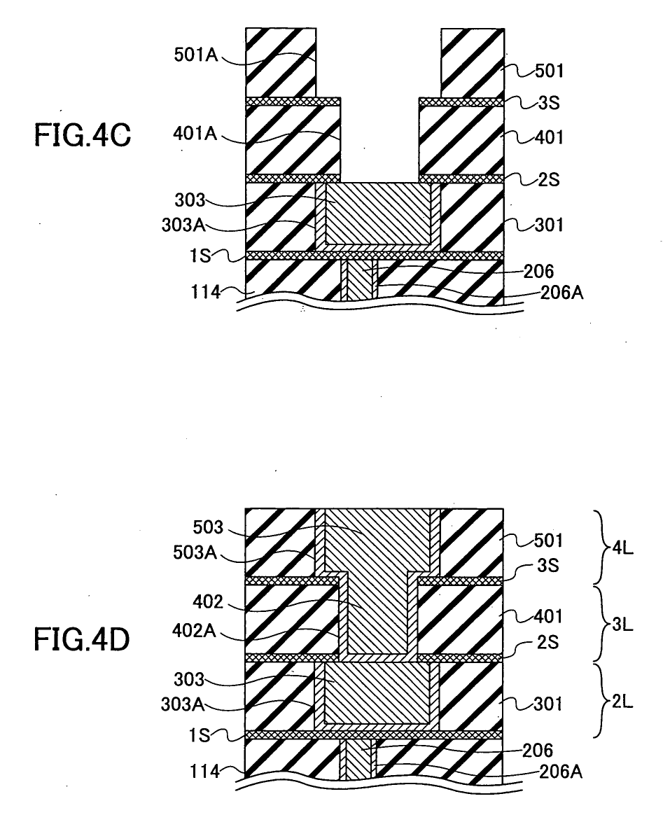

FIGS. 3A through 3C are diagrams showing processes to form the second wiring structure 2L of the semiconductor device 100. FIGS. 4A through 4D are diagrams showing processes to form the third and fourth wiring structures 3L and 4L of the semiconductor device 100. In FIGS. 3A through 3C and 4A through 4D, a part of the cross section of the wiring structures of the semiconductor device 100 is shown, and the other parts thereof are omitted. Explanation of repeated processes is omitted.

In a process shown in FIG. 3A, first, the dielectric inter layer 301 of SiO is formed on the etching stopper layer 1S by, for example, the plasma TEOS method or an HDP-CVD (high density plasma CVD) method.

In addition, if necessary, as the dielectric inter layer 301, any one of an SiON film, an SiOC film, an SiCO(H) film, and a fluorine added SiO film (FSG film) can be used. Further, as the dielectric inter layer 301, a low ferroelectric film made of, for example, HSQ (hydrogen silsesquioxane) can be formed by a spin coat method. In addition, the dielectric inter layer 301 can be formed by sandwiching a film formed by the spin coat method between films formed by the CVD method. Further, when an annealing process or a plasma process is applied after forming the dielectric inter layer 114, the film quality is increased due to elimination of hydrogen and water. With this, the ferroelectric capacitor can be prevented from being damaged by eliminating hydrogen and water. The dielectric inter layers 401, 501, 601, and 701 can be formed by the same method as that for the dielectric inter layer 301.

Next, in a process shown in FIG. 3B, after applying patterning to the dielectric inter layer 301 by a photolithography method, etching is applied to the dielectric inter layer 301. In this case, the etching stopper layer 1S functions as an etching stopper. After etching the dielectric inter layer 301, etching is applied to the etching stopper layer 1S and the contact wiring 206 is exposed.

Next, in a process shown in FIG. 3C, the barrier film 303A of TaN is formed by, for example, a sputtering method. A seed layer of Cu is formed on the barrier film 303A by a sputtering method and a Cu film is formed by a plating method, and then the Cu film is flattened by a CMP method. With this, the trench wiring section 303 is formed and the second wiring structure 2L is formed.

Next, the etching stopper layer 2S is formed to cover the dielectric inter layer 301 and the trench wiring section 303 by the same method as that for the etching stopper layer 1S.

There are several methods to form a wiring structure on the etching stopper layer 2S. When, for example, Cu wiring is used for the wiring structure, a dual damascene method or a single damascene method may be used. In the present embodiment, the dual damascene method is used for forming the third and fourth wiring structures 3L and 4L.

In a process shown in FIG. 4A, the dielectric inter layer 401 is formed on the etching stopper layer 2S, the etching stopper layer 3S is formed on the dielectric inter layer 401, and the dielectric inter layer 501 is formed on the etching stopper layer 3S. The dielectric inter layers 401 and 501 can be formed by the same method as that for the dielectric inter layer 301. The etching stopper layer 3S can be formed by the same method as that for the etching stopper layer 2S.

Next, in a process shown in FIG. 4B, after applying patterning to the dielectric inter layer 501 by a photolithography method, etching is applied to the dielectric inter layer 501, the etching stopper layer 3S, and the dielectric inter layer 401. In this case, the etching stopper layer 2S is used as the etching stopper. After this, the trench wiring section 303 is exposed by etching the etching stopper layer 2S. With this, a via hole 401A is formed. In this, when etching is applied to the etching stopper layer 3S, it is preferable that a gas and conditions used for the etching be different from those at the time of etching the dielectric inter layers 501 and 401.

Next, in a process shown in FIG. 4C, after applying patterning to the dielectric inter layer 501 by a photolithography method, a trench 501A is formed by applying etching to the dielectric inter layer 501. In this case, the etching stopper layer 3S is used as the etching stopper.

Next, in a process shown in FIG. 4D, the barrier films 402A and 503A of TaN are formed by, for example, a sputtering method. After forming a seed layer of Cu on the barrier films 402A and 503A by a sputtering method, a Cu film is formed by a plating method, and the Cu film is flattened by a CMP method. With this, the trench wiring section 503 and the via plug wiring section 402 are formed so that the third and fourth wiring structures 3L and 4L are formed.

After this, similarly, the etching stopper layer 4S is formed on the fourth wiring structure 4L. Further, the dielectric inter layer 601, the via plug wiring sections, the etching stopper layer 5S, the dielectric inter layer 701, the global wiring section 702, and the protection film 801 are formed.

In the present embodiment, the dual damascene method is used; however, the wiring structures can be formed by the single damascene method. In case of the single damascene method, for example, the via plug wiring section 402 and the trench wiring section 503 are formed separately. That is, after forming the third wiring structure 3L, the etching stopper layer 3S is formed on the third wiring structure 3L, and the fourth wiring structure 4L is formed on the etching stopper layer 3S.

Conventionally, an SiN layer is generally used for the etching stopper layer in a multi-layer wiring structure of Cu. On the other hand, in the present embodiment, as the etching stopper layer, a layer which includes a hydrogen diffusion preventing layer is used. Therefore, in the present embodiment, the influence of the diffusion of hydrogen generated at the time of forming the etching stopper layer is eliminated; further, the diffusion of hydrogen and water which enters from, for example, the outside is prevented in other processes. With this, a semiconductor device having a high-quality ferroelectric capacitor can be manufactured while preventing the deterioration of the ferroelectric capacitor.

In addition, since plural hydrogen diffusion preventing layers are formed, a semiconductor device that has resistance against water entering from the outside and low deterioration with the passage of time can be obtained.

Further, when the plural etching stopper layers are formed, it is not necessary to form all the etching stopper layers with the same material; different materials can be used depending on the necessity. For example, the etching stopper layers 1S and 2S are formed with Al₂O₃ which has a high hydrogen diffusion preventing effect, and the etching stopper layers 3S through 5S are formed with SiN which conventionally has a high Cu diffusion preventing effect.

In addition, as the etching stopper layer, a layer can be used in which the following layers are stacked by combining them or materials of the layers are mixed. That is, there is a layer which has a high stopper effect for etching, that is, a layer which has high etching selectivity with a dielectric inter layer; a layer which has a high Cu diffusion preventing effect; and a layer which has a high hydrogen diffusion preventing effect. By combining plural layers or plural materials, a balance among the stopper effect for etching, the Cu diffusion preventing effect, and the hydrogen diffusion preventing effect can be adjusted.

[Manufacturing Method 3]

As described above, when H₂O is diffused in a manufacturing process of a FeRAM, there is a risk that the ferroelectric capacitor may be deteriorated. Therefore, it is difficult to execute a scrubber process (H₂O jet process) which removes particles so as to increase the yield in manufacturing the semiconductor device.

In order to solve this problem, in manufacturing the semiconductor device described above, a method is provided, which increases the yield in manufacturing of the semiconductor device by removing the particles on the surface of the semiconductor substrate without using H₂O.

FIG. 5 is a schematic diagram showing a low temperature aerosol cleaning method which is used in manufacturing the semiconductor device shown in FIG. 1. The low temperature aerosol cleaning method is an existing technology disclosed in Patent Documents 1 and 2.

Referring to FIG. 5, the low temperature aerosol cleaning method is explained. In the cleaning method, inactive mixed gases of, for example, argon and nitrogen are transformed into aerosol Z at a very low temperature, the aerosol Z is blown on the surface of a substrate Wf from a nozzle N at highspeed, and particles Pa on the surface of the substrate Wf are removed.

In a case where the cleaning method described above is used for the semiconductor device 100 shown in FIG. 1, when the cleaning method is compared with the scrubber process, since H₂O is not used, the deterioration of the ferroelectric capacitor caused by hydrogen and H₂O is prevented, and the particles on the surface of the substrate are removed. With this, the yield in manufacturing the semiconductor device can be increased.

Especially, after forming the ferroelectric capacitor, it is difficult to use the scrubber process. Therefore, the low temperature aerosol cleaning method which does not use H₂O is effective because the method does not have a risk of diffusing hydrogen and H₂O.

In addition, when a process that uses H₂O, for example, the scrubber process or a cleaning process that uses H₂O, is applied to a hydrogen diffusion preventing layer made of, for example, Al₂O₃, this causes damage to the hydrogen diffusion preventing layer. Therefore, when the low temperature aerosol cleaning method is used in processes after forming the hydrogen diffusion preventing layer, the deterioration of the ferroelectric capacitor caused by hydrogen and H₂O is prevented, and the particles on the surface of the substrate are removed. With this, the yield in manufacturing of the semiconductor device can be increased.

Further, in the semiconductor device 100 shown in FIG. 1, in order to prevent the deterioration of the ferroelectric capacitor, it is preferable that an annealing process or a plasma process be applied so as to remove water after forming the dielectric inter layers. However, in some cases, the number of particles on the dielectric inter layers is increased by the annealing process or the plasma process. Therefore, in order to remove the particles, it is preferable that the low temperature aerosol cleaning method be used after the annealing process or the plasma process.

In addition, since the processes of forming the dielectric inter layers 301, 401, 501, 601, and 701 are executed after forming the ferroelectric capacitor, a cleaning process that uses water such as the scrubber process is difficult. Therefore, when the low temperature aerosol cleaning method is used after the annealing process or the plasma process, the number of particles can be reduced while eliminating deterioration of the ferroelectric capacitor caused by hydrogen and water.

Further, when the low temperature aerosol cleaning method is used after the annealing process or the plasma process after the dielectric inter layers are formed, the number of particles can be reduced while eliminating the risk of damage to the hydrogen diffusion preventing layer formed before the dielectric inter layers when the scrubber process is used.

As described above, in the cleaning method of the semiconductor device that has both the ferroelectric capacitor which may be damaged by hydrogen or water and the hydrogen diffusion preventing layer which may be damaged by the cleaning, the low temperature aerosol cleaning method which does not use H₂O is preferable.

For example, it is preferable that the low temperature aerosol cleaning method be used after the plasma process or the annealing process after the dielectric inter layer 114 shown in FIG. 2C is formed for the above reason.

In addition, it is preferable that the low temperature aerosol cleaning method be used after the plasma process or the annealing process after the dielectric inter layer 301 shown in FIG. 3A is formed and after the dielectric inter layer 401 or 501 shown in FIG. 4A is formed for the above reason.

Further, the low temperature aerosol cleaning method can be used after the plasma process or the annealing process after the dielectric inter layer 601 or 701 is formed.

After etching a dielectric inter layer, it is necessary to remove residuals and particles. Therefore, when the low temperature aerosol cleaning method is used after etching the dielectric inter layer 114 to form the contact hole shown in FIG. 2C, after etching the dielectric inter layer 301 to form a trench 301A shown in FIG. 3B, after etching the dielectric inter layers 401 and 501 to form the via hole 401A shown in FIG. 4B, and after etching the dielectric inter layer 501 to form the trench 501A shown in FIG. 4C, this method is preferable for the above reason.

In addition, a cleaning process is required after a CMP process so as to remove particles; therefore, it is preferable to use the low temperature aerosol cleaning method after the CMP process.

Further, the low temperature aerosol cleaning method can be used in the processes to form the ferroelectric capacitor. When this method is used, the yield in manufacturing of the semiconductor device can be increased by removing the particles without damaging the ferroelectric capacitor.

For example, the low temperature aerosol cleaning method can be used after forming the lower electrode 201, the ferroelectric layer 202, or the upper electrode 203. In addition, the low temperature aerosol cleaning method can be used after annealing the lower electrode 201, the ferroelectric layer 202, or the upper electrode 203 is formed.

### Second Embodiment

When a hydrogen diffusion preventing layer is used as an etching stopper layer, it is desirable that etching selectivity with the dielectric inter layer be high. However, when the hydrogen diffusion preventing layer is not used as the etching stopper layer, since the etching selectivity with the dielectric inter layer is high, in some cases, the etching efficiency becomes worse.

For example, as shown in FIG. 2C, in case of the hydrogen diffusion preventing layer 204 into which the contact wirings 205 and 206 of the ferroelectric capacitor are inserted, when the contact wirings 205 and 206 are formed by etching the dielectric inter layer 114 and the hydrogen diffusion preventing layer 204, at the time of etching, an etching gas and the etching conditions must be different between etching the dielectric inter layer 114 and etching the hydrogen diffusion preventing layer 204. Consequently, the etching efficiency at the time of forming the contact holes becomes worse.

In order to solve this problem, in the present embodiment, parts of the hydrogen diffusion preventing layer 204 where the contact holes are to be formed are selectively removed before executing etching to form the contact holes. With this, the contact holes are easily formed.

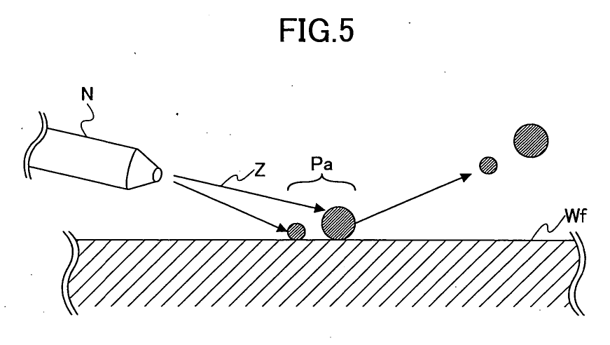

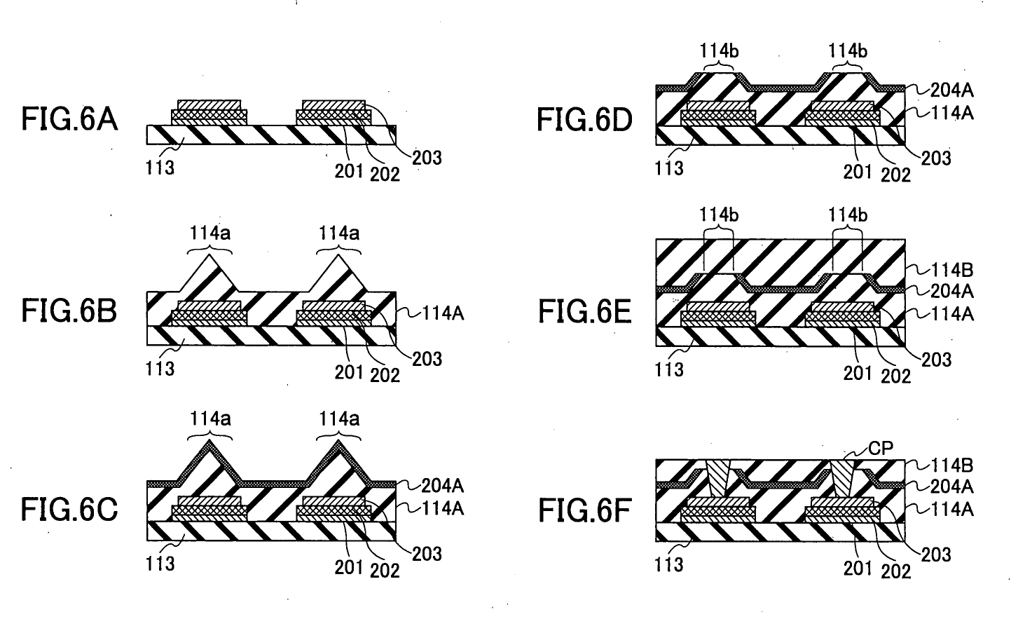

FIGS. 6A through 6F are diagrams showing processes to form a wiring structure of the semiconductor device 100 shown in FIG. 1 according to a second embodiment of the present invention. In FIGS. 6A through 6F, a part of the cross section of the semiconductor device 100 is shown, and the other parts thereof are omitted. Explanation of repeated processes is omitted. In FIGS. 6A through 6F, the reference numbers of some elements are different from those shown in FIG. 1.

First, in a process shown in FIG. 6A, a hydrogen diffusion preventing layer is not formed and adjacent two ferroelectric capacitors are formed.

Next, in a process shown in FIG. 6B, an insulation layer 114A made of, for example, SiO is formed to cover the ferroelectric capacitors by an HDP-CVD method. In this case, it is preferable that the insulation layer 114A be formed by applying a bias voltage to the silicon substrate (not shown). When the HDP-CVD method is used, dissociation of a gas which is used to form a layer progresses and film forming by ions dominates; therefore, coverage for a micro-fabrication pattern is enlarged.

For example, when it is attempted to increase the integration level of the ferroelectric capacitors, an interval between adjacent two ferroelectric capacitors becomes small; consequently, there is a problem in that voids are formed when the insulation layer is formed.

In the present embodiment, since the insulation layer 114A is formed by the HDP-CVD method, generation of voids between the ferroelectric capacitors is prevented.

In addition, when a bias voltage is applied to the silicon substrate at this time, a sputtering effect due to the ions becomes large. Therefore, the forming property of the insulation layer 114A becomes excellent and the generation of voids is restrained.

Further, in the HDP-CVD method, by the sputtering effect due to ions, as shown in FIG. 6B, the insulation layer which is formed on the ferroelectric capacitor has a protrusion shape, and a protrusion 114a is formed on the ferroelectric capacitor.

The material of the insulation layer 114A is not limited to SiO; fluorine added SiO (FSG) or SiON can be used.

Next, in a process shown in FIG. 6C, like the process shown in FIG. 2B, a hydrogen diffusion preventing layer 204A made of, for example, an Al oxide such as Al₂O₃ is formed on the insulation layer 114A.

As the material of the hydrogen diffusion preventing layer 204A, any one of an Al nitrogen oxide, a Ta oxide, a Ti oxide can be used rather than an Al oxide.

Next, in a process shown in FIG. 6D, selective etching is applied to a part of the hydrogen diffusion preventing layer 204A formed on the protrusion 114a by, for example, a CMP method, and the part formed on the protrusion 114a is removed. With this, an exposure section 114b of the insulation layer 114A is formed.

When a general purpose CMP method is used, a part of the hydrogen diffusion preventing layer 204A formed on the protrusion 114a can be selectively etched. In this case, a part of the insulation layer 114A at the position of the protrusion 114a is also removed and the exposure section 114b is flattened.

Next, in a process shown in FIG. 6E, an insulation layer 114B is formed to cover the hydrogen diffusion preventing layer 204A and the exposure section 114b, and then the surface of the insulation layer 114B is flattened by a CMP method.

In this case, as the insulation layer 114B, an SiO film, an SiON film, an FSG film, and so on can be formed by the HDP-CVD method. However, it is not necessary that the coverage be excellent compared with the case of the insulation layer 114A. Therefore, the insulation layer 114B can be formed by a plasma TEOS method or a spin coat method.

Next, in a process shown in FIG. 6F, patterning is applied to the insulation layer 114B by a photolithography method, a contact hole is formed by applying plasma etching using, for example, a CF type gas, and contact wiring CP is formed in the contact hole. In this, the contact hole passes through from the surface of the insulation layer 114B to the upper electrode 203.

In addition, it is preferable that a barrier film be formed at a boundary part between the contact wiring CP and the insulation layers 114A and 114B.

The contact wiring CP can be formed by W, Al, or Cu. The forming method of the contact wiring CP and the barrier film is the same as that shown in FIG. 2C. In this, in FIGS. 6A through 6F, contact wiring connecting to the lower electrode 201 is omitted for convenience.

Conventionally, when a contact hole is formed, an etching gas and the etching condition must be different between etching an insulation layer and etching a hydrogen diffusion preventing layer. Consequently, it takes time to form the contact hole. Further, in some cases, a step is formed in the contact hole or the shape of the contact hole is not normally formed.

According to the present embodiment, when a contact hole for contact wiring connecting to a ferroelectric capacitor is formed by etching, the etching can be effectively executed without changing the gas and the etching conditions, and an abnormal shape of the contact hole can be prevented.

In addition, since a part of the hydrogen diffusion preventing layer where the contact hole is to be formed is selectively removed, the other parts of the hydrogen diffusion preventing layer where the contact hole is not to be formed are not removed. Therefore, the hydrogen diffusion preventing layer can prevent hydrogen and water from being diffused, and the ferroelectric capacitor can be prevented from deteriorating.

That is, the contact wiring can be formed effectively by separately etching the hydrogen diffusion preventing layer and the insulation layer while preventing the diffusion of hydrogen and preventing the deterioration of the ferroelectric capacitor.

In addition, when the hydrogen diffusion preventing layer is selectively removed, it is not necessary to add a mask process and a photolithography process. Therefore, the processes are not complicated.

As described above, according to the embodiments of the present invention, in a semiconductor device having a ferroelectric capacitor, the deterioration of the ferroelectric capacitor can be prevented by preventing the diffusion of hydrogen.

In addition, in a case where Cu is used as a wiring material of the semiconductor device having the ferroelectric capacitor, when a wiring structure is formed, the deterioration of the ferroelectric capacitor can be prevented by preventing the diffusion of hydrogen. Further, the semiconductor device having a high-quality ferroelectric capacitor and the manufacturing method thereof can be provided.

Moreover, when a semiconductor device having a ferroelectric capacitor is manufactured, the yield in manufacturing the semiconductor device can be increased by removing particles while preventing the deterioration of the ferroelectric capacitor.

Further, when a semiconductor device having a ferroelectric capacitor is manufactured, since a hydrogen diffusion preventing layer is formed, the deterioration of the ferroelectric capacitor can be prevented by preventing the diffusion of hydrogen and H₂O. In addition, since a part of the hydrogen diffusion preventing layer is selectively removed, when contact wiring of the ferroelectric capacitor is formed, the etching efficiency can be excellent.

Further, the present invention is not limited to the embodiments, but various variations and modifications may be made without departing from the scope of the present invention.

### INDUSTRIAL APPLICABILITY

According to the embodiments of the present invention, since a hydrogen diffusion preventing layer is included in the semiconductor device, the present invention can be applied to a semiconductor device which needs to prevent hydrogen diffusion.

In addition, since particles are removed and the yield in manufacturing of a semiconductor device is increased, the present invention can be applied to a semiconductor device for which a high yield is required.

Further, since a part of the hydrogen diffusion preventing layer is selectively removed, the present invention can be applied to a semiconductor device requiring high etching efficiency.

What is claimed is:

1. A semiconductor device which includes a ferroelectric capacitor formed on a substrate and a wiring structure formed on the ferroelectric capacitor, wherein:
the wiring structure comprises a dielectric inter layer and a Cu wiring section formed in the dielectric inter layer; and
an etching stopper layer including a hydrogen diffusion preventing layer is formed so as to face the dielectric inter layer.

2. The semiconductor device as claimed in claim 1, wherein:
a different wiring structure which includes a different dielectric inter layer and a different Cu wiring section formed in the different dielectric inter layer is formed so as to face the etching stopper layer at the opposite side of the dielectric inter layer.

3. The semiconductor device as claimed in claim 1, wherein:
the hydrogen diffusion preventing layer includes any one of an Al oxide, an Al nitride, a Ta oxide, a Ta nitride, a Ti oxide, and a Zr oxide.

4. The semiconductor device as claimed in claim 1, wherein:
the etching stopper layer includes any one of an SiO layer, an SiON layer, and an SiN layer.

5. The semiconductor device as claimed in claim 1, wherein:
the etching stopper layer has a structure in which any one of an SiO layer, an SiON layer, and an SiN layer is stacked with the hydrogen diffusion preventing layer.

6. The semiconductor device as claimed in claim 1, wherein:
the ferroelectric capacitor comprises a first electrode and a second electrode, and the Cu wiring section is connected to the first electrode or the second electrode.

7. A manufacturing method of a semiconductor device which includes a step of forming a ferroelectric capacitor on a substrate and a step of forming a wiring structure on the ferroelectric capacitor, wherein:
the step of forming the wiring structure comprises;
a step of forming a first wiring structure which includes a wiring section and a first dielectric inter layer on the ferroelectric capacitor;
a step of forming an etching stopper layer which includes a hydrogen diffusion preventing layer on the first wiring structure; and
a step of forming a second wiring structure which includes a Cu wiring section and a second dielectric inter layer on the etching stopper layer.

8. A manufacturing method of a semiconductor device which includes a step of forming a ferroelectric capacitor on a substrate and a step of forming a wiring structure on the ferroelectric capacitor, the method comprising the step of:
cleaning a layer of the semiconductor device with low temperature aerosol including an inactive gas.

9. The manufacturing method of the semiconductor device as claimed in claim 8, wherein:
the step of cleaning a layer of the semiconductor device is executed after the step of forming the ferroelectric capacitor.

10. The manufacturing method of the semiconductor device as claimed in claim 8, further comprising the step of:
forming a hydrogen diffusion preventing layer between the ferroelectric capacitor and the wiring structure after the step of forming the ferroelectric capacitor.

11. A manufacturing method of a semiconductor device, comprising the steps of:
forming a ferroelectric capacitor on a substrate;
forming an insulation layer on the ferroelectric capacitor by a high density plasma CVD method so that a protrusion of the insulation layer is formed on the ferroelectric capacitor;
forming a hydrogen diffusion preventing layer on the insulation layer;
forming an exposure section so that a part of the insulation layer is exposed by selectively removing a part of the hydrogen diffusion preventing layer on the protrusion by a CMP method; and
forming a contact wiring in a contact hole formed from the exposure section to an electrode of the ferroelectric capacitor.
